(19) United States
(12) Patent Application Publication
(10) Pub. No.: US 2025/0327182 A1
(43) Pub. Date: Oct. 23, 2025

(54) DIFFUSER FOR UNIFORM GAS DELIVERY IN CROSS-FLOW REACTORS

(71) Applicant: ASM IP Holding B.V., Almere (NL)

(72) Inventors: Daner Abdula, Chandler, AZ (US); Herbert Terhorst, Amersfoort (NL)

(21) Appl. No.: 19/181,454

(22) Filed: Apr. 17, 2025

Related U.S. Application Data
(60) Provisional application No. 63/637,038, filed on Apr. 22, 2024.

(51) Int. Cl. C23C 16/455

(52) U.S. Cl. CPC C23C 16/45563; C23C 16/45559

(57) ABSTRACT

Diffuser includes a top surface and a bottom surface that extend from an inlet to a wall. The top and the bottom are separated by a separation distance. The separation distance includes at least a first separation distance at the inlet of the diffuser and a second separation distance at the wall such that the first separation distance is greater than the second separation distance. That is, at least a part of the top surface is tapered.

### CROSS-REFERENCE TO RELATED APPLICATIONS

This application is a nonprovisional of, and claims priority to and the benefit of, U.S. Provisional Patent Application No. 63/637,038, filed Apr. 22, 2024 and entitled “DIFFUSER FOR UNIFORM GAS DELIVERY IN CROSS-FLOW REACTORS,” which is hereby incorporated by reference herein.

### FIELD OF INVENTION

The present disclosure generally relates to fabricating semiconductor devices. More particularly, the disclosure relates to cross-flow reactors and components, systems including the reactors and components, and methods of using the reactors, components, and systems.

### BACKGROUND OF THE DISCLOSURE

Gas-phase reactors, such as chemical vapor deposition (CVD) reactors, including, for example atomic layer deposition (ALD) reactors, can be used for a variety of applications, including forming layers on a substrate surface. Such reactors can be used to deposit, etch, clean, and/or treat layers on a substrate to form semiconductor devices, flat panel display devices, photovoltaic devices, microelectromechanical systems (MEMS), and the like.

A typical gas-phase reactor system includes a reactor including a reaction chamber, one or more precursor gas sources fluidly coupled to the reaction chamber, one or more carrier or purge gas sources fluidly coupled to the reaction chamber, a gas distribution system to deliver gases (e.g., the precursor gas(es) and/or carrier or purge gas(es)) to a surface of a substrate, and an exhaust source fluidly coupled to the reaction chamber.

Cross-flow reactors are a type of gas-phase reactor that are particularly useful when fast throughput and/or fast purging of a reaction chamber is desired-such as for ALD deposition. In cross-flow reactors, gases generally enter a reaction chamber at one end of the reaction chamber, flow laterally across a substrate within the reaction chamber, and exit at a second end of the reaction chamber. Gases generally enter the reaction chamber through a diffuser which attempts to distribute and/or mix the precursors prior to flow entering the reaction chamber.

The diffusers in conventional systems are typically constant. That is, the gas(es) enter the diffuser and are distributed across the width of the reactor in a fixed way that is dependent on the diffuser geometry. This redistribution creates a specific flow velocity profile upon gases entering the reaction chamber. In turn, the resulting film thickness deposited on the substrate is non-uniform. The material builds up along the edges such that the thickness of the deposited material along the outer edges of one half of the substrate is greater than that deposited elsewhere on the substrate. Accordingly, improved diffuser designs to manage the flow of the material are desired.

### SUMMARY OF THE DISCLOSURE

A diffuser, comprises an inlet, wherein processing material enters the diffuser at the inlet prior to flowing through a reaction chamber. The inlet is at an intersection of a first axis, a second axis and a third axis, wherein the first axis, the second axis and the third axis are perpendicular to each other. A wall is coupled to the diffuser and the reaction chamber wherein processing material flowing through the diffuser turns at the wall and enters the reaction chamber. The diffuser further comprises a top surface extending from the inlet to the wall and a bottom surface extending from the inlet to the wall. The bottom surface is separated by the top surface by a separation distance and the separation distance is parallel to the third axis. Further, the separation distance further includes a first separation distance at the inlet and a second separation distance at the wall, and the first separation distance is greater than the second separation distance.

A method of manufacturing a diffuser is provided. The method includes defining an inlet at a first axis, a second axis and a third axis, wherein the first axis, the second axis and the third axis are perpendicular to each other. The method further includes coupling a wall of the diffuser with the inlet by coupling a top surface of the diffuser to the inlet and the wall such that it extends from the inlet to the wall, and by coupling a bottom surface of the diffuser to the inlet and the wall such that it extends from the inlet to the wall. The bottom surface extends along a plane parallel to the plane defined by the first axis and the second axis. The method also includes coupling the wall with the inlet by coupling a right surface extending from the inlet to the wall such that the right surface is further coupled to the bottom surface and the top surface, and by coupling a left surface extending from the inlet to the wall such that the left surface is further coupled to the bottom surface and the top surface. The right surface and the left surface define a separation distance between the bottom surface and the top surface, wherein the separation distance is parallel to the third axis such that the separation distance at the inlet is greater than the separation distance at the wall.

A reactor system comprises a material source configured to provide a material to be deposited on a substrate. A diffuser is fluidly coupled to the material source, wherein the diffuser comprises a top surface and a bottom surface. The reactor system also includes a cross-flow reaction chamber is fluidly coupled to the diffuser, wherein the reaction chamber is configured to deposit the material onto a surface of a substrate. The system further includes a wall fluidly coupled to diffuser and the reaction chamber, such that the material flowing through the diffuser from the material source flows to the reaction chamber through the wall. The top surface and the bottom surface is separated by a separation distance, and the separation distance is tapered from an inlet coupled to the material source to the wall.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 illustrates a perspective view of diffuser in a reactor system in accordance with exemplary embodiments of the disclosure;

FIG. 2 illustrates a side view of the diffuser in FIG. 1 in accordance with exemplary embodiments of the disclosure;

FIG. 3 illustrates a front view of a left side of the diffuser of FIG. 1 in accordance with exemplary embodiments of the disclosure;

FIG. 4 illustrates a cross-sectional view of the diffuser of FIG. 1 in accordance with exemplary embodiments of the disclosure;

FIG. 5 illustrates a flow diagram of a method for manufacturing a diffuser such as the one in FIG. 1 in accordance with exemplary embodiments of the disclosure;

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

As set forth in more detail below, various embodiments of the disclosure relate to gas-phase reactors and reactor systems that include a variable-height reaction chamber and/or a spacer to help define a gap between a susceptor and a base plate of the reactor.

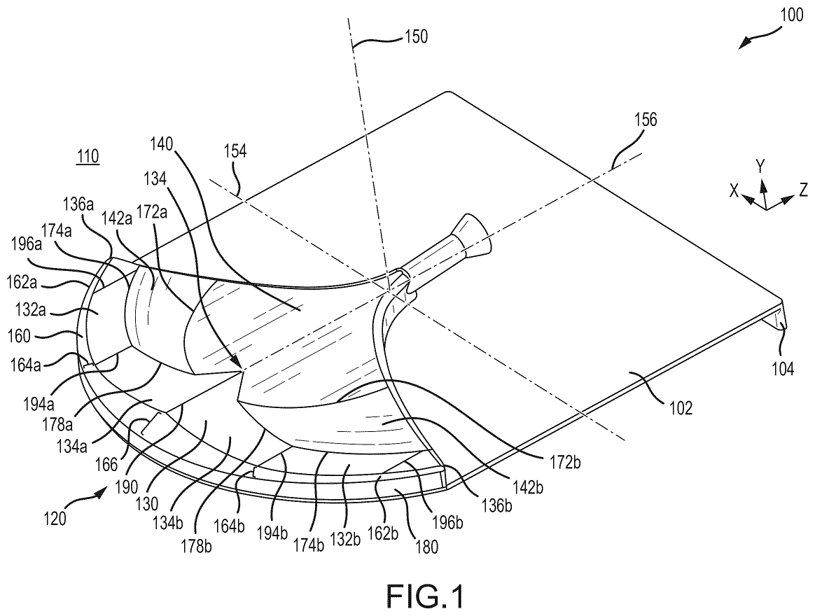

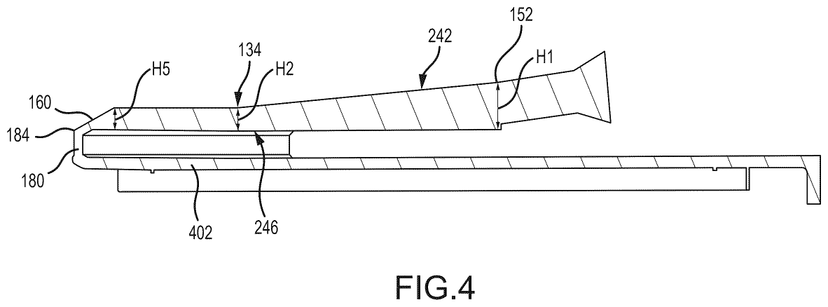

FIGS. 1-4 illustrate sections of a gas-phase reactor system 100 in accordance with exemplary embodiments of the disclosure. System 100 includes a reactor 110. Reactor 110 may be used to deposit material onto a surface of a substrate, etch material from a surface of substrate, clean a surface of substrate, treat a surface of substrate, deposit material onto a surface within reaction chamber, clean a surface within reaction chamber, etch a surface within reaction chamber, and/or treat a surface within reaction chamber 402 (see FIG. 4). Reactor 110 can be a standalone reactor or part of a cluster tool. Further, reactor 110 can be dedicated to deposition, etch, clean, or treatment processes, or reactor 110 may be used for multiple processes-e.g., for any combination of deposition, etch, clean, and treatment processes. By way of examples, reactor 202 may include a reactor typically used for chemical vapor deposition (CVD) processes, such as atomic layer deposition (ALD) processes.

Reaction chamber 402 is a cross-flow reaction chamber. During operation, gases enter reaction chamber 402 via diffuser 120 and flow horizontally through reaction chamber 402 to an exhaust conduit. As seen in FIG. 1, gas flowing through the reaction chamber 402 enters diffuser 120 at inlet 152, hits wall 180 and is output into reaction chamber 402. Inlet 152 is aligned along axes 150, 156 and 158. As seen in FIG. 4 (a cross-sectional view of diffuser 120), diffuser 120 includes a tapered distance between a top surface 242 and bottom surface 246 of diffuser 120. In exemplary embodiments, the height of diffuser 120 between top surface 242 and bottom surface 246 tapers from a large height at inlet 152 to a lesser height as the top surface 242 and bottom surface 246 meet wall 180.

In exemplary embodiments, diffuser 120 includes a back section 140. In exemplary embodiments, diffuser 120 includes a left section 142a and a right section 142b. In exemplary embodiments, diffuser 120 includes a central section 130. In exemplary embodiments, central section 130 further includes a central left section 134a and a central right section 134b. In exemplary embodiments, central section 130 further includes a central far left section 132a and central far right section 132b. In exemplary embodiments, central section 130 includes a central left end (point) 136a and a central right end (point) 136b. In exemplary embodiments, diffuser 120 includes a front section 160.

In exemplary embodiments, the distance (H1) between top surface 242 and bottom surface 246 at inlet 152 is greater than 4 mm. In some exemplary embodiments, distance H1 at inlet 152 is greater than 10 mm. In exemplary embodiments, distance (H2) between top surface 242 and bottom surface 246 at intersection point 134, where back section 140, central section 130 and left section 142a and right section 142b intersect, is less than or equal to distance H1. In exemplary embodiments, distance H2 at intersection point 134 is between about 3 mm and 12 mm. In exemplary embodiments, distance H2 is between about 4 mm and 10 mm. In some exemplary embodiments, distance H2 is about 4 mm. In some exemplary embodiments, distance H2 is about 7.75 mm. In some exemplary embodiments, distance H2 is about 10 mm.

Similarly, in exemplary embodiments, distance (H3) between top surface 242 and bottom surface 246 extending along the intersecting edge 172a between back section 140 and left section 142a and along the intersecting edge 172b between back section 140 and right section 142b is less than or equal to distance H1. In exemplary embodiments, distance H3 may be equal to distance H2. In exemplary embodiments, distance H3 may be slightly less than distance H2. For example, in some exemplary embodiments, the difference between distance H2 and H3 may be 1 mm or less.

Further, in exemplary embodiments, distance between top surface 242 and bottom surface 246 along the intersecting edge 174a (including edge 178a) between left section 142a and central section 130, and distance between top surface 242 and bottom surface 246 along the intersecting edge 174b (including edge 178b) between right section 142b and central section 130 is less than distance H3. In exemplary embodiments, top surface 242 slopes down from intersecting edge 172b to intersecting edge 174b in section 142b to adjoin with bottom surface 246. Similarly, in exemplary embodiments, top surface 242 slopes down from intersecting edge 172a to intersecting edge 174a in section 142a to adjoin with bottom surface 246.

In exemplary embodiments, central section 130 includes a central left section 134a defined from edge 190 to edge 194a and further defined from edge 178a to edge 170. Similarly, in exemplary embodiments, central section 130 further includes a central right section 134b defined from edge 190 to edge 194b and further defined from edge 178b to edge 170. In exemplary embodiments, central section 130 includes a central far left section 132a defined from edge 194a to 196a and further defined from edge 174a to edge 170. Similarly, in exemplary embodiments, central section 130 further includes a central far right section 132b defined from edge 194b to edge 196b and further defined from edge 174b to edge 170.

As shown in FIGS. 1-4, in exemplary embodiments, edge 190 extends from intersection point 134 to edge 170. As shown in FIG. 1, edge 190 is aligned along axis 156. In exemplary embodiments, distance (H5) between top surface 242 and bottom surface 246 at intersection of edge 190 and edge 170 is between 2 mm and 12 mm. In some exemplary embodiments, distance H5 is about 2.24 mm. In some exemplary embodiments, distance H5 is about 4 mm. In some exemplary embodiments, distance H5 is about 7.75 mm. In some exemplary embodiments, distance H5 is about 10 mm.

As shown in FIGS. 1-4, central section 130 of diffuser 120 extends from center edge 190 to end point 136b on the right side of diffuser 120 and further extends from center edge 190 to end point 136a on the left side of diffuser 120. End point 136a is located at an intersection point of a first endpoint axis and a second endpoint axis, wherein the first endpoint axis is parallel to axis 154 and wherein the second endpoint axis is parallel to axis 156. Similarly, end point 136b is located at an intersection of a first endpoint axis and a third endpoint axis, wherein the third endpoint axis is parallel to axis 156.

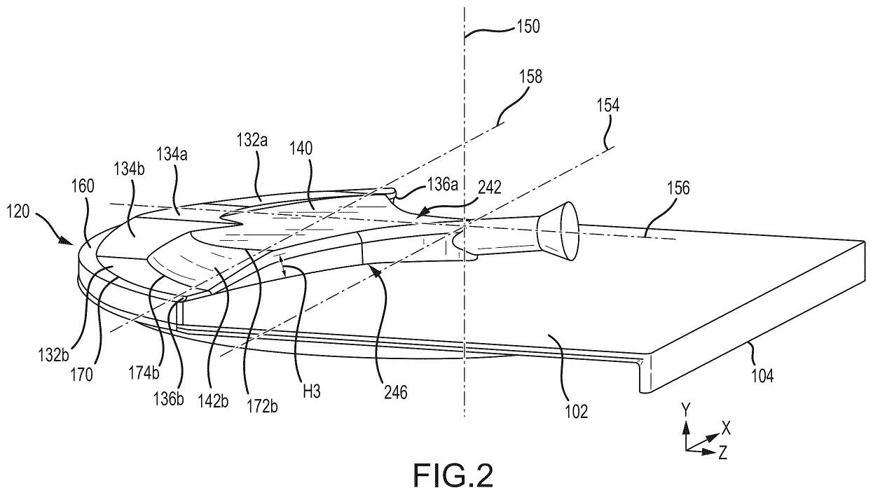

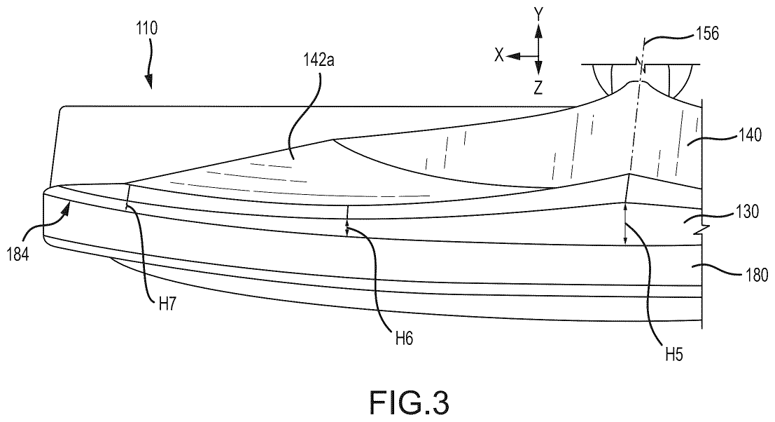

As shown in FIG. 3, in exemplary embodiments, distance between top surface 242 and bottom surface 246 in section 130 decreases as section 130 extends from central edge 190 to end points 136a and 136b. Central edge 190 is aligned along axis 156. Further end points 196a and 196b are equidistant from central edge 190. In exemplary embodiments, distance (H7) between top surface 242 and bottom surface 246 at edge 196a, and between top surface 242 and bottom surface 246 at edge 196b is less than distance H5. In exemplary embodiments, distance H7 is between 1 mm and 4 mm. In exemplary embodiments, distance H7 is at least one of 1.12 mm, 2.14 mm or 2.24 mm. In an exemplary embodiment (not shown), distance H7 may be equal to distance H5. As shown in FIG. 2, end points 136a and 136b are aligned along an axis 158 that is parallel to axis 154.

In the exemplary embodiment shown in FIGS. 1-4, top surface 242 of diffuser 120 in section 130 extends from center edge 190 to edge 196a, and further extends from center edge 190 to edge 196b, such that distance H7 is less than distance H5. In exemplary embodiments, top surface 242 may extend from center edge 190 to edge 196a, and from center edge 190 to edge 196ain a linear fashion such that the slope of top surface 242 between edge 190 and edge 196a remains constant. Similarly, the slope of top surface 242 between edge 190 and 196b remains constant.

In exemplary embodiments, top surface 242 may extend from center edge 190 to edge 196a in a non-linear manner. As discussed herein, non-linear is defined to mean that the slope of top surface 242 between two points is not necessarily constant. As shown in FIGS. 1-4, in exemplary embodiments, section 130 further includes edge 194a that divides section 130 into a center left section 134a and center far left section 132a. Similarly, in exemplary embodiments, section 130 further includes edge 194b that divides section 130 into a center right section 134b and center far right section 132b. The distance (H6) between top surface 242 and bottom surface 246 at edges 194a and 194b is less than distance H5. In exemplary embodiments, distance H6 may be greater than distance H7. In exemplary embodiments, distance H6 is between 3 mm and 5 mm. In exemplary embodiments, distance H6 is 3.7 mm.

In exemplary embodiments, top surface 242 of diffuser 120 further tapers down from edge 170 to edge 184 to form a tapered section 160. Accordingly, edge 184 is formed at the intersection of tapered section 160 and wall 180. As shown in FIG. 4, any material flowing through diffuser 120 is focused through tapered section 160 and further through wall 180. Thus, the variation in distance between top surface 242 and 246 at different parts (162a, 162b, 164a, 164b, 166) through section 160 allows the flow of the material to be redirected to the center and provides a higher velocity as the material passes through wall 180. The wall shear increases as this material then turns along edge 184 and flows through wall 180. Such an arrangement then provides for a more uniform application of the material as it flows through reaction chamber 402 and then on to a wafer. Thus, the material build-up on the wafer is significantly less in comparison to conventional systems.

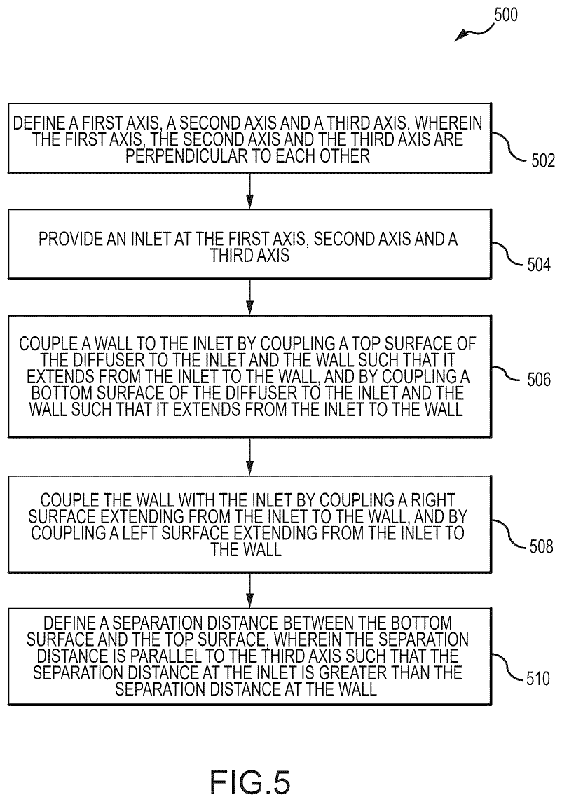

FIG. 5 illustrates a method of manufacturing a diffuser of a reactor system, e.g., diffuser 120 (shown in FIGS. 1-4). Method 500 includes defining a first axis, a second axis and a third axis, such as axis 156, 157 and 158, as shown with box 502. These three axes are perpendicular to each other. Method 500 further includes providing an inlet (such as inlet 152) at the first axis, second axis and the third axis, as shown with box 504.

Method 500 also includes coupling a wall (such as wall 180) to the inlet by coupling a top surface (such as surface 242) of the diffuser to the inlet and the wall such that it extends from the inlet to the wall, and by coupling a bottom surface (such as surface 246) of the diffuser to the inlet and the wall, as shown with box 506 (See FIGS. 1-4). Method 500 further includes coupling the wall with the inlet by coupling a right surface extending from the inlet to the wall, and by coupling a left surface extending from the inlet to the wall, as shown with box 508. The right surface is coupled to the bottom and the top surface and the left surface is coupled to the bottom surface and the top surface. Accordingly, method 500 further includes defining a separation distance between the bottom surface and the top surface, wherein the separation distance is parallel to the third axis such that the separation distance at the inlet is greater than the separation distance at the wall, as shown with box 510.

In exemplary embodiments, method 500 further includes providing a first edge (such as 170) separating the top surface into a back section (such as 140, 142a, 142b, 130) and the front section (such as 160), such that the difference in separation distance at the inlet and at the first edge is smaller than the difference in separation distance at the first edge and the wall. Further, in exemplary embodiments, method 500 includes tapering the separation distance from the first edge to the wall. Further, in exemplary embodiments, method 500 includes defining the separation distance of the top surface from the first edge to the wall within a range of 2 mm to 12 mm. In further exemplary embodiments of method 500, the separation distance can vary in different sections of the diffuser. For example, the separation distance in different parts of section 130 may be different.

Although exemplary embodiments of the present disclosure are set forth herein, it should be appreciated that the disclosure is not so limited. For example, although the reactors and systems are described in connection with various specific configurations, the disclosure is not necessarily limited to these examples. Various modifications, variations, and enhancements of the exemplary systems and methods set forth herein may be made without departing from the spirit and scope of the present disclosure.

Unless otherwise noted, the subject matter of the present disclosure includes all novel and nonobvious combinations and subcombinations of the various systems, components, and configurations, and other features, functions, acts, and/or properties disclosed herein, as well as any and all equivalents thereof. Further, the headings provided herein, if any, are for convenience only and do not necessarily affect the scope or meaning of the devices and methods disclosed herein.

1. A diffuser, comprising:
an inlet, wherein processing material enters the diffuser at the inlet prior to flowing through a reaction chamber, wherein the inlet is at an intersection of a first axis, a second axis and a third axis, wherein the first axis, the second axis and the third axis are perpendicular to each other;
a wall coupled to the diffuser and the reaction chamber wherein processing material flowing through the diffuser turns at the wall and enters the reaction chamber;
a top surface extending from the inlet to the wall;
a bottom surface extending from the inlet to the wall, wherein the bottom surface is separated by the top surface by a separation distance;
wherein the separation distance is parallel to the third axis, and wherein the separation distance further includes a first separation distance at the inlet and a second separation distance at the wall, wherein the first separation distance is greater than the second separation distance.

2. The diffuser of claim 1, wherein the top surface further comprises a first edge between the inlet and the wall such that the separation distance comprises a third separation distance at the first edge, wherein difference between the third separation distance and the second separation distance is greater than difference between the first separation distance and the third separation distance.

3. The diffuser of claim 2, further comprising:
a first end point such that the first end point is at an intersection point of a first endpoint axis and a second endpoint axis, wherein the first endpoint axis is parallel to the first axis and wherein the second endpoint axis is parallel to the second axis;
a second end point such that the second end point is at an intersection point of the first endpoint axis and a third endpoint axis, wherein the third endpoint axis is parallel to the second endpoint axis and the second axis;
a central edge wherein the central edge is aligned along the second axis, wherein the first end point and the second end point are equidistant from the central edge; and
wherein the third separation distance comprises a fourth separation distance, wherein the fourth separation distance is the separation distance at the point of intersection of the first edge and the central edge, wherein the third separation further comprises a fifth separation distance, wherein the fifth separation distance is the separation distance at the point of intersection of the first endpoint and the first edge, and wherein the third separation further comprises a sixth separation distance, wherein the sixth separation distance is the separation distance at the point of intersection of the second endpoint and the first edge; and
wherein the fourth separation distance is greater than the fifth separation distance and wherein the fourth separation distance is greater than the sixth separation distance.

4. The diffuser of claim 3, wherein the fourth separation distance is between 2 mm and 12 mm.

5. The diffuser of claim 3, wherein the fifth separation distance and the sixth separation distance is between 2 mm and 4 mm.

6. The diffuser of claim 3, wherein the top surface comprises:
a first tapered section coupled to the central edge, the first edge, and the first end point, wherein the first tapered section is tapered from the central edge to the first end point; and
a second tapered section coupled to the central edge, the first edge, and the second end point, wherein the second tapered section is tapered from the central edge to the second end point;

7. The diffuser of claim 6, wherein the first tapered section has a linear slope, and the second tapered section has a linear slope.

8. The diffuser of claim 3, further comprising:
a right edge, wherein the right edge is parallel to the second axis;
a left edge, wherein the left edge is parallel to the second axis;
wherein the right edge and the left edge are equidistant from the central edge, and wherein distance between the right edge and the first end point is the same as distance between the left edge and the second end point; and
wherein the third separation distance comprises a seventh separation distance at the point of intersection of the first edge and the right edge, wherein the third separation distance comprises an eighth separation distance at a point of intersection of the first edge and the left edge, wherein the fourth separation distance is greater than the seventh separation distance and wherein the fourth separation distance is greater than the eighth separation distance.

9. The diffuser of claim 8, wherein the seventh separation distance is greater than the fifth separation distance and the eighth separation distance is greater than the sixth separation distance.

10. The diffuser of claim 9, wherein the seventh separation distance and the eighth separation distance are between 3 mm and 5 mm.

11. The diffuser of claim 8, wherein the fourth separation distance is 10 mm, wherein the fifth and sixth separation distance is 2.14 mm, and wherein the seventh and eighth separation distance is 3.7 mm.

12. The diffuser of claim 8,
wherein the first tapered section comprises a fourth tapered section coupled to the central edge, the first edge and the right edge, wherein the fourth tapered section is tapered from the central edge to the right edge;
wherein the first tapered section comprises a fifth tapered section coupled to the right edge, the first edge and the first end point, wherein the fifth tapered section is tapered from the right edge to the first endpoint;
wherein the second tapered section comprises a sixth tapered section coupled to the central edge, the first edge and the left edge, wherein the sixth tapered section is tapered from the central edge to the left edge; and
wherein the second tapered section comprises a seventh tapered section coupled to the first edge, the left edge and the second endpoint, wherein the seventh tapered section is tapered from the left edge to the second endpoint.

13. The diffuser of claim 2, wherein the top surface comprises a front tapered section coupled to the first edge and the wall, wherein the front tapered section is tapered from the first edge to the wall.

14. The diffuser of claim 13, wherein the top surface comprises multiple tapered sections.

15. The diffuser of claim 14, wherein the multiple tapered sections further comprise:
a back section coupled to the inlet and a back edge, wherein the back section is tapered from the inlet to the back edge;
a right section coupled to the back section at the back edge and further coupled to a mid-right edge, wherein at least a portion of the right section is tapered from the back edge to the mid-right edge;
a left section coupled to the back section at the back edge and further coupled to a mid-left edge, wherein at least a portion of the left section is tapered from the back edge to the mid-left edge.

16. A method of manufacturing a diffuser, comprising:
defining an inlet at a first axis, a second axis and a third axis, wherein the first axis, the second axis and the third axis are perpendicular to each other;
coupling a wall of the diffuser with the inlet by coupling a top surface of the diffuser to the inlet and the wall such that it extends from the inlet to the wall, by coupling a bottom surface of the diffuser to the inlet and the wall such that it extends from the inlet to the wall, wherein the bottom surface extends along a plane parallel to the plane defined by the first axis and the second axis;
coupling the wall with the inlet by coupling a right surface extending from the inlet to the wall, wherein the right surface is further coupled to the bottom surface and the top surface and by coupling a left surface extending from the inlet to the wall, wherein the left surface is further coupled to the bottom surface and the top surface such that the right surface and the left surface define a separation distance between the bottom surface and the top surface, wherein the separation distance is parallel to the third axis such that the separation distance at the inlet is greater than the separation distance at the wall.

17. The method of claim 16, wherein coupling the top surface to the inlet and the wall further comprises providing a first edge separating the top surface into a back section and a front section, such that difference in separation distance at the inlet and at the first edge is smaller than difference in separation distance at the first edge and the wall.

18. The method of claim 17, wherein coupling the top surface to the inlet and the wall further comprises tapering the separation distance from the first edge to the wall.

19. The method of claim 18, wherein the separation distance of the top surface from the first edge to the wall is between 2 mm and 12 mm.

20. A reactor system comprises:
a material source configured to provide a material to be deposited on a substrate;
a diffuser fluidly coupled to the material source, wherein the diffuser comprises a top surface and a bottom surface;
a cross-flow reaction chamber fluidly coupled to the diffuser, wherein the reaction chamber is configured to deposit the material onto a surface of a substrate;
a wall fluidly coupled to diffuser and the reaction chamber, such that the material flowing through the diffuser from the material source flows to the reaction chamber through the wall; and
wherein the top surface and the bottom surface is separated by a separation distance, and
wherein the separation distance is tapered from an inlet coupled to the material source to the wall.
